(19) United States
(12) Patent Application Publication
(10) Pub. No.: US 2005/0180103 A1
(43) Pub. Date: Aug. 18, 2005

(54) Electrical apparatus and heat sink device thereof

(76) Inventor: Hung Chung Ku, Shulin City (TW)

Correspondence Address: BIRCH STEWART KOLASCH & BIRCH, PO BOX 747, FALLS CHURCH, VA, 22040-0747, US

(21) Appl. No.: 11/043,159

(22) Filed: Jan. 27, 2005

(30) Foreign Application Priority Data
Feb. 13, 2004 (TW) 093103557

(51) Int. Cl. H05K 7/20

(52) U.S. Cl. 361/695; 361/697

(57) ABSTRACT

A heat sink device is disposed in an electrical apparatus. The heat sink device comprises a fan and a transferring tube. In this case, the transferring tube has a first end and a second end. The first end is near to the fan, and the second end is near to a first heat source. When the fan rotates to produce airflow, the heat generated by the first heat source is transferred from the second end to the first end.

### BACKGROUND OF THE INVENTION

1. Field of Invention

The invention relates to an electrical apparatus and a heat sink device thereof and, in particular, to an electrical apparatus and a heat sink device that employs Bernoulli theorem.

2. Related Art

During these years, the demand and the dependence of the electrical apparatus have increased; such as portable computers. On the basis of the convenience of portable computers, the demand for portable computers has increased in a great amount. However, the interior components of the electrical apparatus may generate significant amounts of heat. If this heat is not continuously removed from the electrical apparatus, the electrical apparatus may overheat.

Hereinafter, take a notebook as an example. Please refer to FIG. 1, the conventional notebook 1 includes a fan 11, a fixing member 12, a plurality of fins 13, a basement 14 and at least one heat conducting tube 15. The fixing member 12 is a shell, and has an opening. The fan 11 is disposed on the fixing member 12 by screws. The fins 13 are disposed on the basement 14 that connects with the fixing member 12. One end of the heat conducting tube 15 connects with a heat sink 2, and the other end of the heat conducting tube 15 connects with the basement 14. The heat conducting tube 15 is formed of a heat conductive material, such as metal. The heat sink 2 connects with a heat source.

During normal operation, the interior heat source of the electrical apparatus generates heat may cause temperature to increase. According to the conduction principle, heat generated by the heat source is conducted into the heat sink 2, and then conducted into the basement 14 and the fins 13 by the heat conducting tube 15. The fan 11 disposed on the fixing member 12 rotates to produce airflow, and the airflow moves through the opening and the fins 13, so that heat is transferred away from the system.

The main heat sources of the notebook are a central processing unit (CPU), a video graphics array (VGA) and the likes. There are some conventional methods for dissipating heat. For example, the fins disposed in the notebook may increase the surface area for dissipating heat, increasing the amounts of the heat dissipation openings, or filling the heat conducting liquid in the cavity of the heat conducting tube. However, the conventional heat sink devices could not transfer the heat generated by central processing unit, video graphics array or other heat sources away from the system effectively. Hence, the electrical apparatus may overheat easily.

It is therefore a subjective of the invention to provide a heat sink device that can solve the above-mentioned problems.

### SUMMARY OF THE INVENTION

In view of the above, the invention provides a heat sink device that may remove heat away from the electrical apparatus effectively.

To achieve the above, the heat sink device of the invention employs Bernoulli theorem to remove heat away from the electronic apparatus.

To achieve the above, the heat sink device of the invention is disposed in an electrical apparatus. The heat sink device comprises a fan and a transferring tube. In this case, the transferring tube has a first end and a second end. The first end is near to the fan, and the second end is near to a first heat source. When the fan rotates to produce airflow, the heat generated by the first heat source is transferred from the second end to the first end.

To achieve the above, the electrical apparatus of the invention comprises a casing, a fan and a transferring tube. In this case, the fan is disposed in the casing. The transferring tube has a first end and a second end. The first end is near to the fan, and the second end is near to a first heat source. When the fan rotates to produce airflow, the heat generated by the first heat source is transferred from the second end to the first end.

As mentioned above, in this invention, the amounts of heat in the electrical apparatus may be removed to the outside of the system effectively.

### BRIEF DESCRIPTION OF THE DRAWINGS

The invention will become more fully understood from the detailed description given herein below illustration only, and thus is not limitative of the present invention, and wherein:

FIG. 1 is a schematic view of a conventional heat sink device;

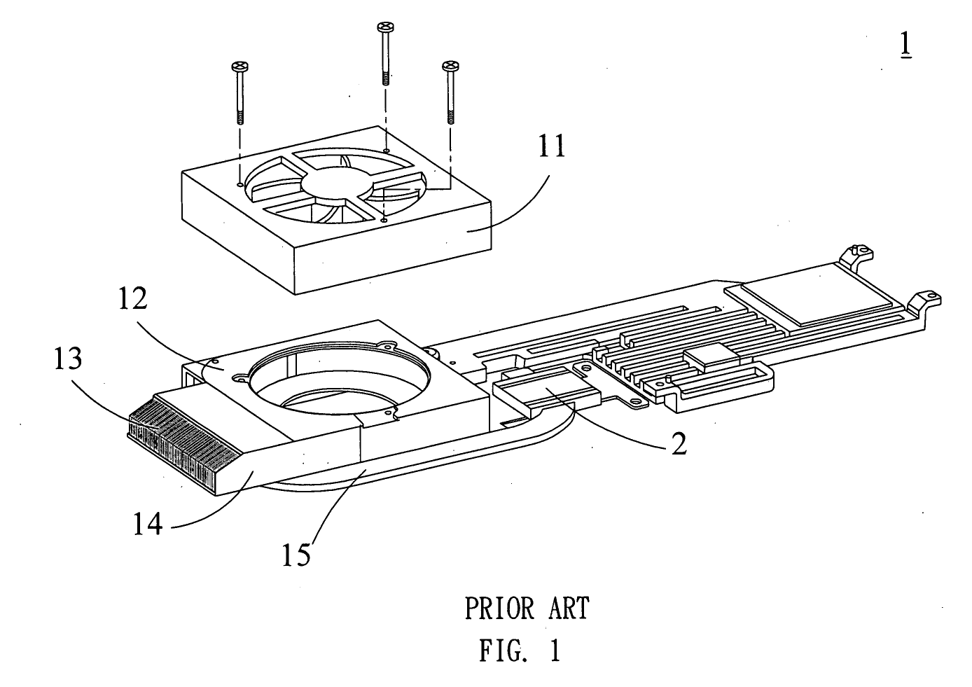

FIG. 2 is a schematic view of a heat sink device in an embodiment of the invention;

FIG. 3 is a schematic view of an another heat sink device in the embodiment of the invention; and

FIG. 4 is a schematic view of a transferring tube in the embodiment of the invention.

### DETAILED DESCRIPTION OF THE INVENTION

The present invention will be apparent from the following detailed description, which proceeds with reference to the accompanying drawings, wherein the same references relate to the same elements.

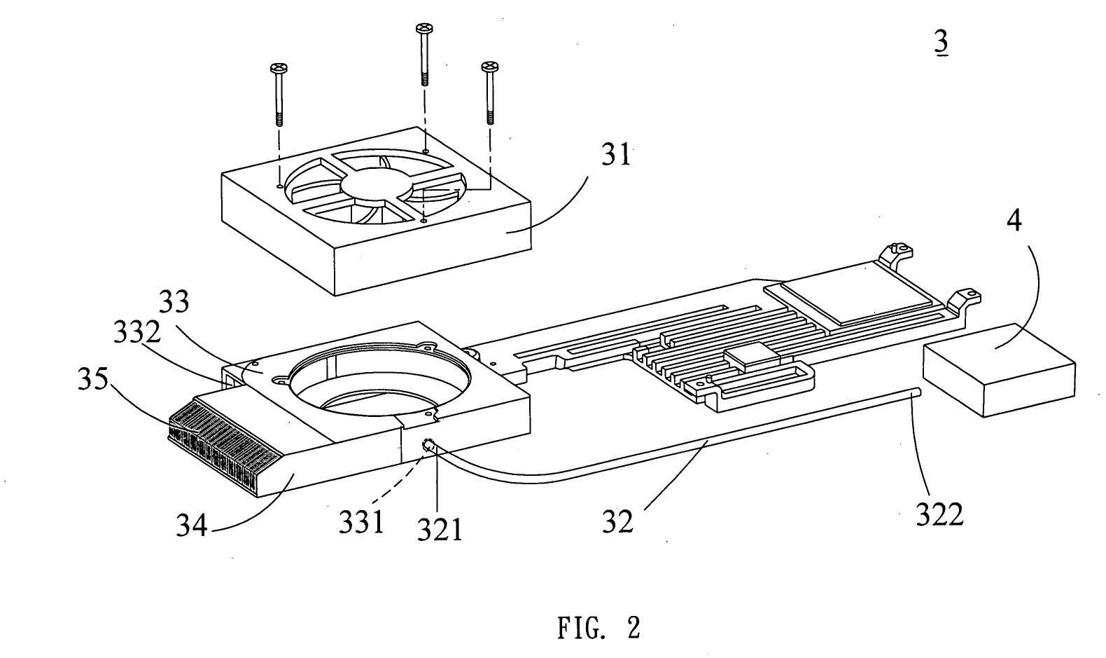

As shown in FIG. 2, the heat sink device 3 according to an embodiment of the invention is disposed in an electrical apparatus. The heat sink device 3 includes a fan 31 and a transferring tube 32. In this embodiment, the fan 31 is disposed in the electrical apparatus. The transferring tube 32 may be hollow, and has a first end 321 and a second end 322. The first end 321 is near to the fan 31, and the second end 322 is near to a first heat source 4.

The first heat source 4 may be an electrical element or an integrated circuit. An opening of the second end 322 faces the first heat source 4, and the diameter of the opening is larger than the diameter of the transferring tube 32.

The heat sink device 3 of the embodiment further includes a fixing member 33, a basement 34 and a plurality of fins 35. The fixing member 33 may be a shell and has an opening 331. The first end 321 of the transferring tube 32 connects with the opening 331 of the fixing member 33. The fan 31 may be fixed on the fixing member 33 by at least one screw. The fixing member 33 connects with the basement 34, and the fins 35 are disposed on the basement 34. When the fan 31 rotates, airflow produced by rotations of the fan 31 flows through the fins 35 and an outlet 332.

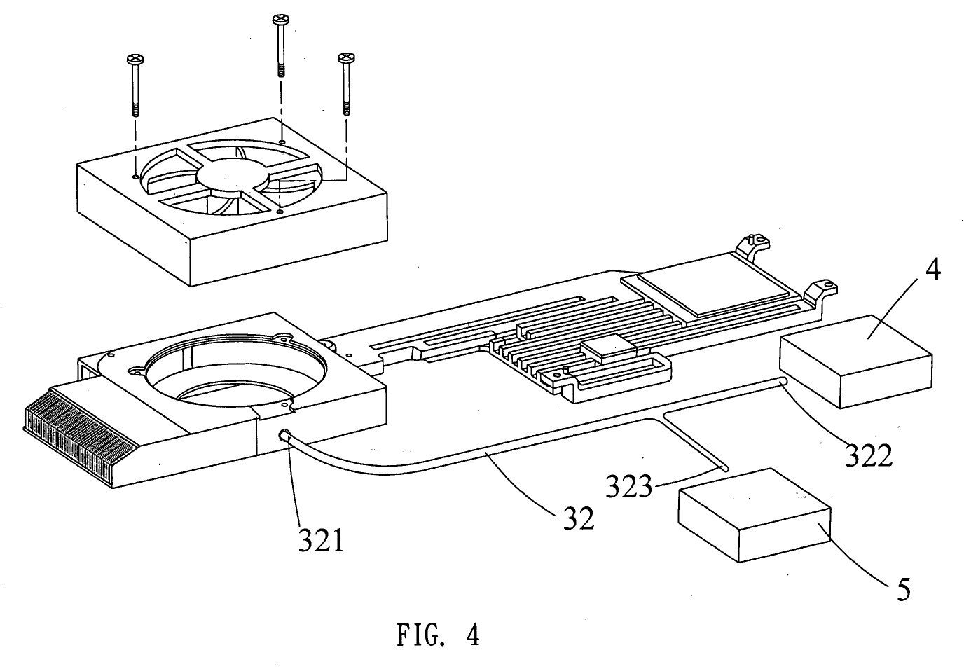

As shown in FIG. 4, the transferring tube 32 of the embodiment further includes a third end 323, which is near to a second heat source 5. Herein, the transferring tube 32 may be Y shaped.

According to Bernoulli theorem, the airflow produced by rotations of the fan 31 may decrease the pressure of the surrounding air. Airflow moves faster, the pressure of the air becomes lower. Simultaneously, the first heat source 4 generates heat, and the heat may cause the air to expand. Further, the expanding air may cause the pressure of the air to increase. There is a difference between high pressure and low pressure. The difference between pressures may cause the hot air produced by the first heat source 4 to move from the second end 322 and the third end 323 to the first end 321. Further, when the airflow produced by rotations of the fan 31 flows through the opening 331 and the fins 35, the heat is moved to the outside of the system. Besides, the fins 35 have larger area for dissipating heat, and thus, maximize the transfer of heat from the heat sink 3 into the surrounding area.

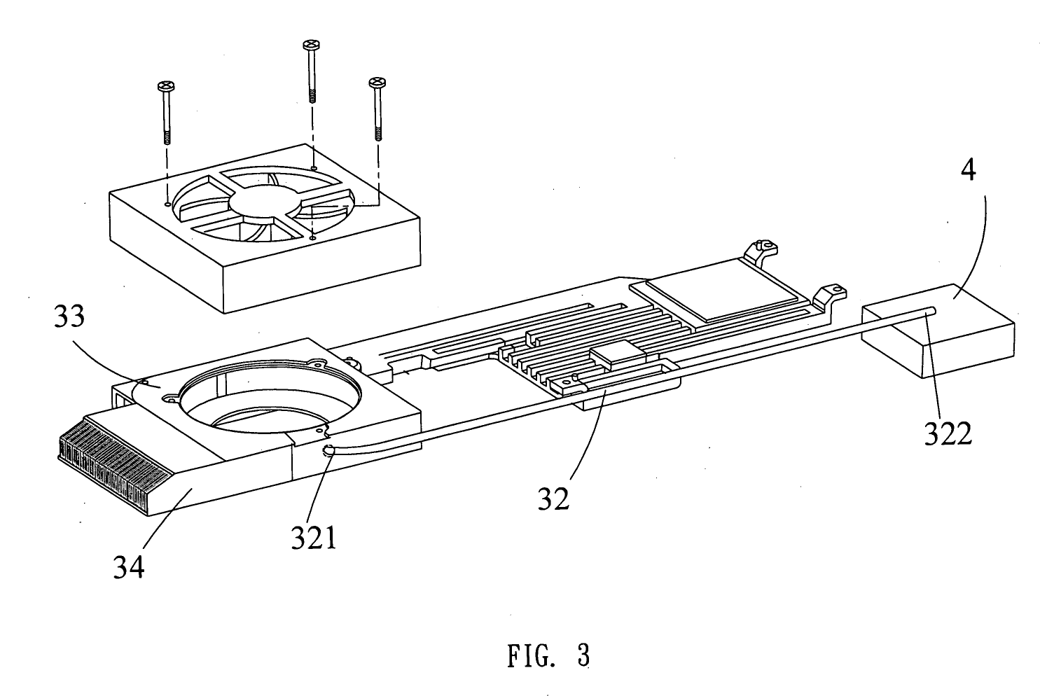

The transferring tube 32 of the embodiment may be made of metal a material or a polymer material. The transferring tube 32 may be a heat conductor. As shown in FIG. 3, when the transferring tube 32 is a heat conductor, a part of the transferring tube 32 which is near to the second end 322 may contact with the first heat source 4, and another part of the transferring tube 32 which is near to the first end. 321 may contact with the fixing member 33 and the basement 34. And, the opening of the second end 322 doesn't face the first heat source 4. Hence, the transferring tube 32 may transfer heat to the outside of the system both by conduction principle and Bernoulli theorem.

The electrical apparatus according to another embodiment of the invention includes a casing, a fan and a transferring tube. In this embodiment, the transferring tube may be hollow, and has a first end and a second end. The first end is near to the fan, and the second end is near to a first heat source. The electrical apparatus further includes a fixing member, a basement and a plurality of fins. The fixing member may be substantially a casing having an opening. The first end connects with the fixing member, and the fan may be fixed on the fixing member by at least one screw. The fixing member connects with the basement, and the fins are disposed on the basement. When the fan rotates, airflow produced by rotations of the fan flows through the opening of the fixing member and the fins. In the present embodiment, the characteristics and functions of the heat sink device is the same as the heat sink device 3 in the first embodiment, and detailed descriptions thereof will be omitted. In the present embodiment, the transferring tube is hollow. The first end is near to the fan, and the second end is near to the first heat source. When the fan rotates to produce the airflow, the hot air produced by the first heat source is moved from the second end to the first end. Therefore, the hot air in the electrical apparatus may be moved to the outside of the system effectively. And, the interior temperature of the system can be controlled.

Although the invention has been described with reference to specific embodiments, this description is not meant to be construed in a limiting sense. Various modifications of the disclosed embodiments, as well as alternative embodiments, will be apparent to persons skilled in the art. It is, therefore, contemplated that the appended claims will cover all modifications that fall within the true scope of the invention.

1. A heat sink device, which is disposed in an electrical apparatus, comprising:
a fan; and
a transferring tube having a first end and a second end, wherein the first end is near to the fan, the second end is near to a first heat source, and when the fan rotates to produce airflow, heat generated by the first heat source is transferred from the second end to the first end.

2. The heat sink device of claim 1, further comprising:
a fixing member having an opening, wherein the fan is fixed on the fixing member, the first end of the transferring tube connects with the opening of the fixing member, and the airflow produced by rotations of the fan flows around the opening.

3. The heat sink device of claim 2, wherein the fixing member is a shell.

4. The heat sink device of claim 2, wherein the first end of the transferring tube is fixed on the fixing member.

5. The heat sink device of claim 1, wherein the transferring tube further comprises a third end, the third end is near to a second heat source, and when the fan rotates to produce the airflow, the heat generated by the second heat source is transferred from the third end to the first end.

6. The heat sink device of claim 5, wherein the transferring tube is Y shaped.

7. The heat sink device of claim 1, wherein the transferring tube is hollow.

8. The heat sink device of claim 1, wherein the first heat source is an electrical element.

9. The heat sink device of claim 1, wherein the first heat source is an integrated circuit.

10. The heat sink device of claim 1, wherein an opening of the second end faces the first heat source.

11. The heat sink device of claim 1, wherein the transferring tube is made of a metal material.

12. The heat sink device of claim 1, wherein the transferring tube is made of a polymer material.

13. The heat sink device of claim 1, wherein the transferring tube is a heat conductor.

14. An electrical apparatus, comprising:
a casing;
a fan disposed in the casing; and
a transferring tube having a first end and a second end, wherein the first end is near to the fan, the second end is near to a first heat source, and when the fan rotates to produce airflow, heat generated by the first heat source is transferred from the second end to the first end.

15. The electrical apparatus of claim 14, further comprising:
a fixing member having an opening, wherein the fan is fixed on the fixing member, the first end of the transferring tube connects with the opening of the fixing member, and the airflow produced by rotations of the fan flows around the opening.

16. The electrical apparatus of claim 15, wherein the fixing member is a shell.

17. The electrical apparatus of claim 15, wherein the first end of the transferring tube is fixed on the fixing member.

18. The electrical apparatus of claim 14, wherein the transferring tube further comprises a third end, the third end is near to a second heat source, and when the fan rotates to produce the airflow, the heat generated by the second heat source is transferred from the-third end to the first end.

19. The electrical apparatus of claim 18, wherein the transferring tube is Y shaped.

20. The electrical apparatus of claim 14, wherein the transferring tube is hollow.

21. The electrical apparatus of claim 14, wherein the first heat source is an electrical element.

22. The electrical apparatus of claim 14, wherein the first heat source is an integrated circuit.

23. The electrical apparatus of claim 14, wherein an opening of the second end faces the first heat source.

24. The electrical apparatus of claim 14, wherein the transferring tube is made of a metal material.

25. The electrical apparatus of claim 14, wherein the transferring tube is made of a polymer material.

26. The electrical apparatus of claim 14, wherein the transferring tube is a heat conductor.
